(19) United States
(12) Patent Application Publication
(10) Pub. No.: US 2025/0301611 A1
(43) Pub. Date: Sep. 25, 2025

(54) DATA CABINET HEAT-DISSIPATING SYSTEM AND METHOD

(71) Applicant: Winconn Systems INC., Taipei City (TW)

(72) Inventor: Jun LIN, Taipei City (TW)

(21) Appl. No.: 18/896,921

(22) Filed: Sep. 26, 2024

(30) Foreign Application Priority Data
Mar. 21, 2024 (CN) 202410328982.0

(51) Int. Cl. H05K 7/20

(52) U.S. Cl. CPC H05K 7/20736; H05K 7/20809

(57) ABSTRACT

A data cabinet heat-dissipating system includes an air exhaust assembly, a flow guide plate, and a water-cooling radiator. The air exhaust assembly includes a ventilation plate and a heat dissipation fan. The flow guide plate includes a flow guide plate and flow guide openings. The water-cooling radiator includes a water cooling plate, heat conducting plates, and water cooling pipes. The flow guide plate accelerates entry of external air into the cabinet. A server in the cabinet generates heat and air flowing through the flow guide plate generates minute airflows that push the heat of the server to the water-cooling radiator, where cold water flows into the water-cooling radiator to cause heat exchange with the heat of the server and heat of the cabinet so subjected to heat exchange with the water-cooling radiator is conveyed to outside for cooling.

### BACKGROUND OF THE INVENTION

### (a) Technical Field of the Invention

The present invention relates to the field of data cabinet heat dissipation technology, and more particularly to a data cabinet heat-dissipating system and method.

### (b) Description of the Prior Art

A cabinet is an independent or self-supporting enclosure that receives and holds electrical or electronic equipment. The cabinet is commonly provided with a door and detachable or non-detachable side boards and rear board. The cabinet is a necessary component of electrical equipment and is a carrier of electrical control equipment and is generally made of cold-rolled steel plates or alloys.

Electrical devices arranged in the cabinet will give off a large amount of heat when put into operation, and such heat causes temperature rise that affects normal operation of the electrical devices arranged in the cabinet and shortens service lives of the electrical device arranged in the cabinet.

### SUMMARY OF THE INVENTION

An objective of the present invention is to provide a data cabinet heat-dissipating system and method aiming to resolve the technical issues of the prior art regarding affecting normal operation of electrical devices arranged in a cabinet and shortening service lives of the electrical devices arranged in the cabinet.

To achieve the above objective, an embodiment of the present invention provides a data cabinet heat-dissipating system, which comprises a cabinet body, a front-door cooling assembly, an air exhaust assembly, and a rear-door cooling assembly, wherein the front-door cooling assembly, the air exhaust assembly, and the rear-door cooling assembly are arranged, in sequence, on the cabinet body, the front-door cooling assembly being arranged at a front end of the cabinet body and located at one side of the air exhaust assembly, the front-door cooling assembly transferring heat inside the cabinet body to outside, the air exhaust assembly being arranged between the front-door cooling assembly and the rear-door cooling assembly and arranged on the cabinet body, the air exhaust assembly transferring heat inside the cabinet body to outside, the rear-door cooling assembly being arranged at a rear end of the cabinet body and located at one side of the air exhaust assembly, the rear-door cooling assembly transferring heat inside the cabinet body to outside.

As an optional solution of the present invention, the front-door cooling assembly comprises a flow guide plate and a hinge, the flow guide plate being fixedly connected to the hinge, the hinge being fixedly connected to the cabinet body, the flow guide plate being rotatably connected by the hinge to the cabinet body, the flow guide plate being formed with flow guide openings, the flow guide openings being arranged as plural ones that are uniformly arranged on the flow guide plate.

As an optional solution of the present invention, the flow guide plate is arranged as two such flow guide plates, each of the flow guide plates being correspondingly formed with two such hinges and fixedly connected to the hinges.

As an optional solution of the present invention, the front-door cooling assembly comprises a flow guide plate, a water-cooling radiator, and a protective screen, the flow guide plate, the water-cooling radiator, and the protective screen being fixedly connected to the cabinet body in sequence from inside to outside, the flow guide plate being formed with a plurality of flow guide openings, the flow guide openings transferring heat inside the cabinet body to outside.

As an optional solution of the present invention, the rear-door cooling assembly comprises an airflow guide plate and a water-cooling radiator, the airflow guide plate and the water-cooling radiator being fixedly connected to the cabinet body in sequence from inside to outside, the airflow guide plate being formed with airflow guide openings, the airflow guide openings transferring heat of the cabinet body to outside.

As an optional solution of the present invention, the water-cooling radiator comprises a water cooling plate, heat conducting plates, and water cooling pipes, the water cooling plate being fixedly connected to the cabinet body, the heat conducting plates and the water cooling pipes being both fixedly connected to the water cooling plate, the heat conducting plates and the water cooling pipes being both arranged as plural ones, the heat conducting plates and the water cooling pipe being sequentially arranged and connected, the water cooling pipe being arranged, in a penetrating form, in the heat conducting plate, the water cooling pipes being of an S-shape.

As an optional solution of the present invention, the air exhaust assembly comprises ventilation plates and heat dissipation fans, the ventilation plates being arranged at a top side of the cabinet body, the ventilation plates being as four such ventilation plates, which are respectively located at four corners of the cabinet body, the ventilation plate being formed with a plurality of airflow passage openings, the heat dissipation fan being fixedly connected to one side of the ventilation plate, the heat dissipation fan discharging heat inside the cabinet body through the airflow passage openings to outside.

Based on the same inventive idea, the present invention also provides a data cabinet heat-dissipating method, and the data cabinet heat-dissipating method comprises the following step:
arranging a front-door cooling assembly, an air exhaust assembly, and a rear-door cooling assembly in sequence in a cabinet body, wherein heat inside the cabinet body passes through the front-door cooling assembly and a water-cooling radiator of the front-door cooling assembly brings away the heat inside the cabinet body, and a water-cooling radiator of the rear-door cooling assembly also brings away heat, so that the front-door cooling assembly and the rear-door cooling assembly forms circulating cooling to hot air inside the cabinet body to lower down a temperature inside the cabinet body, and also, the air exhaust assembly drains the hot air inside the cabinet body to outside of the cabinet body for heat exchange to lower down a temperature inside the cabinet body.

One or multiple technical solutions of the data cabinet heat-dissipating system provided in the embodiment of the present invention at least has one of the following technical effects:

The data cabinet body heat-dissipating system and method provided in the present invention comprises the cabinet body, the front-door cooling assembly, the air exhaust assembly, and the rear-door cooling assembly. Heat inside the cabinet body passes through the flow guide plate of the front-door cooling assembly, and the flow guide openings of the flow guide plate accelerates entry of external air into the cabinet body. When a server inside the cabinet body generates heat, air flowing through the flow guide plate as minute airflows makes the air penetrating to push hot air in the cabinet body toward the water-cooling radiator, and the water-cooling radiator of the front-door cooling assembly brings away the heat in the cabinet body, and also, heat is brought away by the water-cooling radiator of the rear-door cooling assembly. The front-door cooling assembly and the rear-door cooling assembly form circulating cooling for the hot air inside the cabinet body to lower down the temperature inside the cabinet body, and cold water at a relatively low temperature flows through an inlet into the water-cooling radiator to have the hot air of the server and the water-cooling radiator exchange heat to achieve efficient heat exchange with the water-cooling radiator and fulfill heat exchange between the hot air of the cabinet body and the water-cooling radiator to convey heat to the outside for cooling, and also, the hot air of the cabinet body is drained out of the cabinet body by means of the air exhaust assembly to lower down the temperature inside the cabinet body.

### BRIEF DESCRIPTION OF THE DRAWINGS

FIG. 1 is a schematic structure diagram showing a data cabinet heat-dissipating system according to a first embodiment of the present invention.

FIG. 2 is a schematic structure diagram showing an air exhaust assembly of the data cabinet heat-dissipating system according to the first embodiment of the present invention.

FIG. 3 is a schematic structure diagram showing a water-cooling radiator of the data cabinet heat-dissipating system according to the first embodiment of the present invention.

FIG. 4 is a schematic structure diagram showing a flow guide plate of the data cabinet heat-dissipating system according to the first embodiment of the present invention.

FIG. 5 is a schematic structure diagram showing a flow guide plate of the data cabinet heat-dissipating system according to the first embodiment of the present invention.

FIG. 6 is a schematic structure diagram showing a flow guide plate of a data cabinet heat-dissipating system according to a second embodiment of the present invention.

### DETAILED DESCRIPTION OF THE PREFERRED EMBODIMENTS

In the description of the embodiment of the present invention, it is understood that the terms “length”, “width”, “up”, “down”, “front”, “rear”, “left”, “right”, “vertical”, “horizontal”, “top”, “bottom”, “inside”, and “outside” indicating directional or positional relationship are interpreted according to the directional or positional relationship depicted in the drawings and are only adopted for easy illustration of the embodiment of the present invention and simplification of the description, and do not indicate or imply a device or element referred to thereby must have a specific direction or must be constructed and operated in a specific direction, and thus, should not be construed as limiting to the present invention.

Further, the terms “first” and “second” are used only for description purposes and are not construed as indicating or implying relative importance or implicitly suggest the number of a technical feature referred to thereby. Thus, a feature defined with “first” and “second” can explicitly or implicitly includes one or more such feature, unless otherwise specifically stated.

In the embodiment of the present invention, unless otherwise explicitly defined and set, the terms “mounting”, “interconnecting”, “connecting”, and “fixing” should be interpreted in a broad sense, such as being fixedly connected or being detachably connected, or being integrated together; or being mechanically connected or electrically connected; or being directly connected or being indirectly connected through an intermediate medium, or interiors of two elements being in communication with each other or two elements being of a relationship of acting on each other. For those having ordinary knowledge of the technical field, the specific meaning of such terms as used in the embodiment of the present invention can be appreciated according to practical conditions.

### Embodiment 1

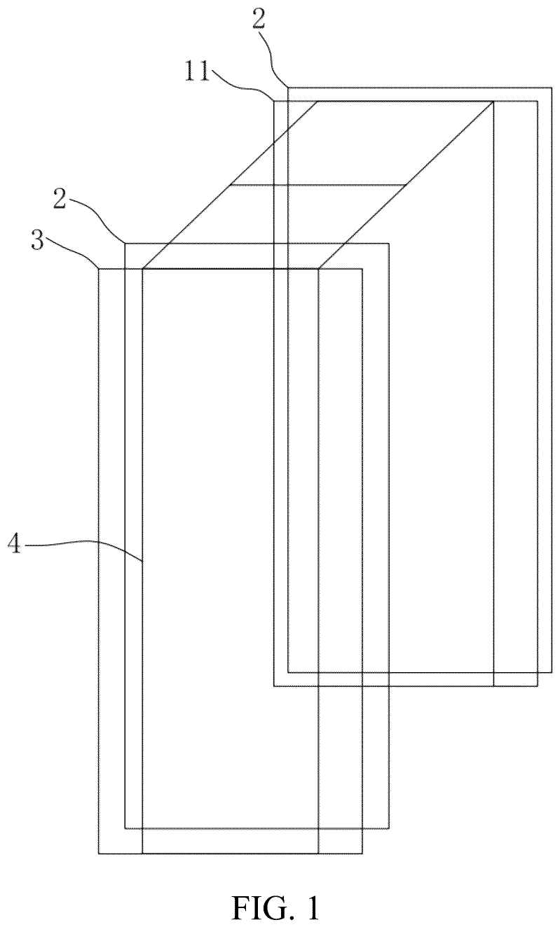

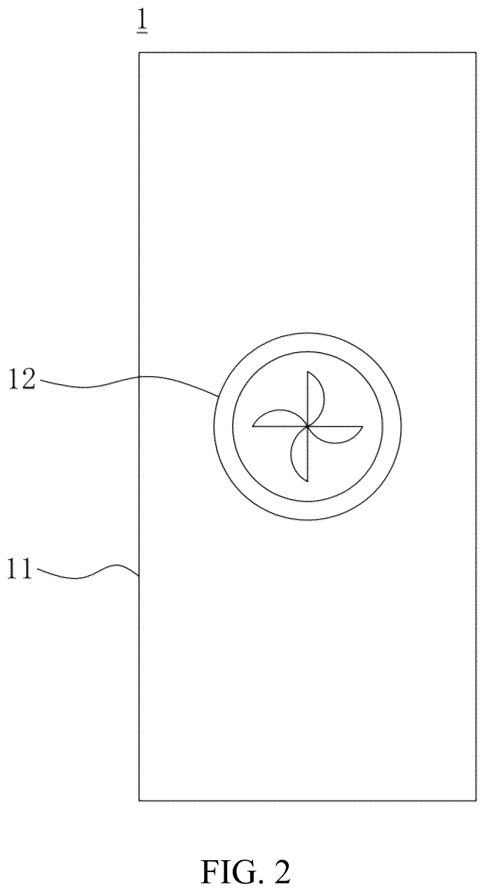

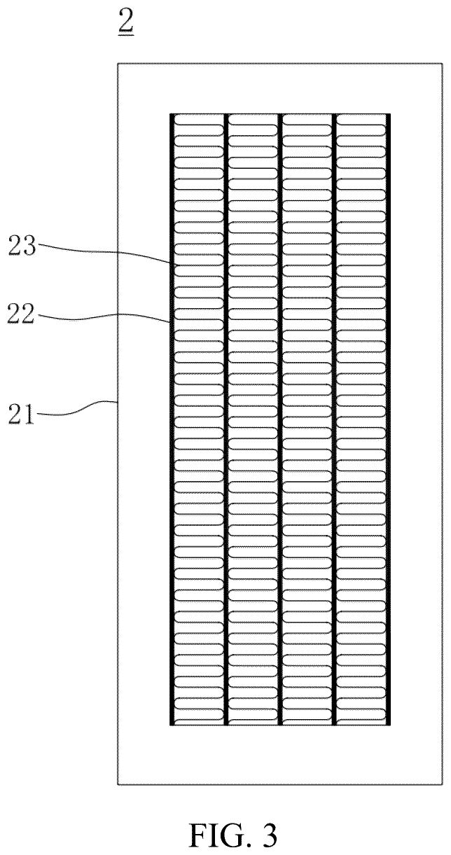

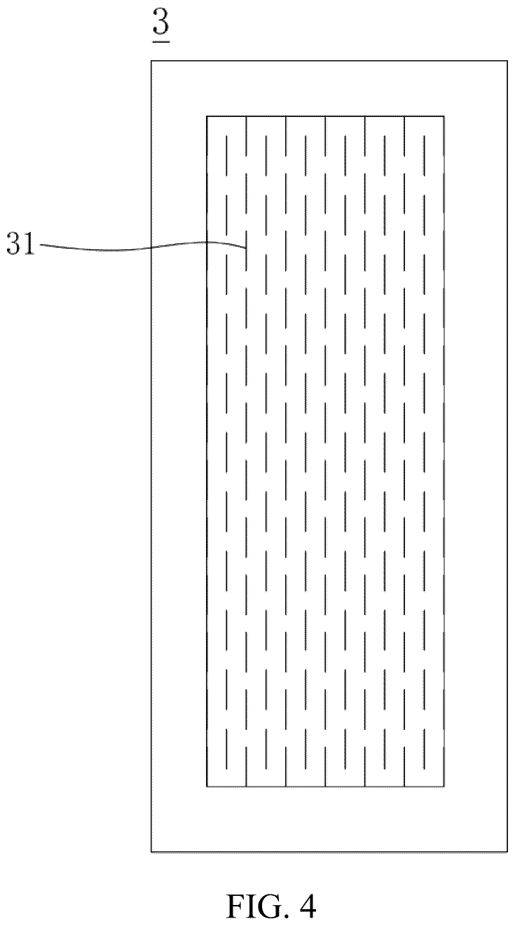

In an embodiment of the present invention, as shown in FIGS. 1-4, a data cabinet heat-dissipating system is provided, comprising a cabinet body 4, a front-door cooling assembly, an air exhaust assembly 1, and the rear-door cooling assembly. The front-door cooling assembly, the air exhaust assembly 1, and the rear-door cooling assembly are arranged, in sequence, on the cabinet body 4. The front-door cooling assembly is arranged at a front end of the cabinet body 4 and is arranged at one side of the air exhaust assembly 1. The front-door cooling assembly transfers heat inside the cabinet body 4 to the outside. The air exhaust assembly 1 is arranged between the front-door cooling assembly and the rear-door cooling assembly and is arranged in the cabinet body 4. The air exhaust assembly 1 conducts heat inside the cabinet body 4 to the outside. The rear-door cooling assembly is arranged at a rear end of the cabinet body 4 and is arranged at one side of the air exhaust assembly 1. The rear-door cooling assembly conducts heat inside the cabinet body 4 to the outside. In the data cabinet body heat-dissipating system and method provided in the present invention, heat inside the cabinet body 4 passes through the flow guide plate 3 of the front-door cooling assembly, and the flow guide openings 31 of the flow guide plate 3 accelerates entry of external air into the cabinet body 4. When a server inside the cabinet body 4 generates heat, air flowing through the flow guide plate 3 as minute airflows makes the air penetrating to push hot air in the cabinet body 4 toward the water-cooling radiator 2, and the water-cooling radiator 2 of the front-door cooling assembly brings away the heat in the cabinet body 4, and also, heat is brought away by the water-cooling radiator 2 of the rear-door cooling assembly. The front-door cooling assembly and the rear-door cooling assembly form circulating cooling for the hot air inside the cabinet body 4 to lower down the temperature inside the cabinet body 4, and cold water at a relatively low temperature flows through an inlet into the water-cooling radiator 2 to have the hot air of the server and the water-cooling radiator 2 exchange heat to achieve efficient heat exchange with the water-cooling radiator 2 and fulfill heat exchange between the hot air of the cabinet body 4 and the water-cooling radiator 2 to convey heat to the outside for cooling, and also, the hot air of the cabinet body 4 is drained out of the cabinet body 4 by means of the air exhaust assembly 1 to lower down the temperature inside the cabinet body 4.

In another embodiment of the present invention, the front-door cooling assembly of the data cabinet heat-dissipating system comprises a flow guide plate 3, a water-cooling radiator 2, and a protective screen, and the flow guide plate 3, the water-cooling radiator 2, and the protective screen are fixedly connected to the cabinet body 4 in sequence from inside to outside. The flow guide plate 3 is formed with a plurality of flow guide openings 31, and the flow guide openings 31 are used to transfer heat inside the cabinet body 4 to the outside. The flow guide openings 31 are extremely small, and when air passes through the flow guide openings 31, external air is accelerated to move into the cabinet to lower down the temperature inside the cabinet.

In another embodiment of the present invention, the rear-door cooling assembly of the data cabinet heat-dissipating system comprises an airflow guide plate and a water-cooling radiator 2, and the airflow guide plate and the water-cooling radiator 2 are fixedly connected to the cabinet body 4 in sequence from inside to outside. The airflow guide plate is formed with airflow guide openings, and the airflow guide openings are used to transfer heat inside the cabinet body 4 to the outside. The airflow guide openings are extremely small, and when air passes through the airflow guide openings, external air is accelerated to move into the cabinet to lower down the temperature inside the cabinet.

In another embodiment of the present invention, the water-cooling radiator 2 of the data cabinet heat-dissipating system comprises a water cooling plate 21, heat conducting plates 22, and water cooling pipes 23. The water cooling plate 21 is fixedly connected to the cabinet body 4, and the heat conducting plates 22 and the water cooling pipes 23 are both uniformly and fixedly connected to the water cooling plate 21. The heat conducting plate 22 and the water cooling pipe 23 are both arranged as plural ones, and the heat conducting plates 22 and the water cooling pipes 23 are sequentially arranged and connected. The water cooling pipes 23 are arranged, in a penetrating form, in the heat conducting plate 22, and the water cooling pipes 23 are of an S-shape. Cold water connected to a cold water pipe makes heat inside the cabinet quickly removed to thereby lower down the temperature inside the cabinet body 4.

In another embodiment of the present invention, the air exhaust assembly 1 of the data cabinet heat-dissipating system comprise ventilation plates 11 and heat dissipation fans 12. The ventilation plates 11 are arranged on a top side of the cabinet body 4, and four ventilation plates 11 are arranged to respectively locate at four corners of the cabinet body 4. The ventilation plate 11 is formed with a plurality of airflow passage openings. The heat dissipation fan 12 is fixedly connected to one side of the ventilation plate 11. The heat dissipation fan 12 allows heat inside the cabinet body 4 to discharge through the airflow passage openings to the outside to thereby reduce heat inside the cabinet body 4.

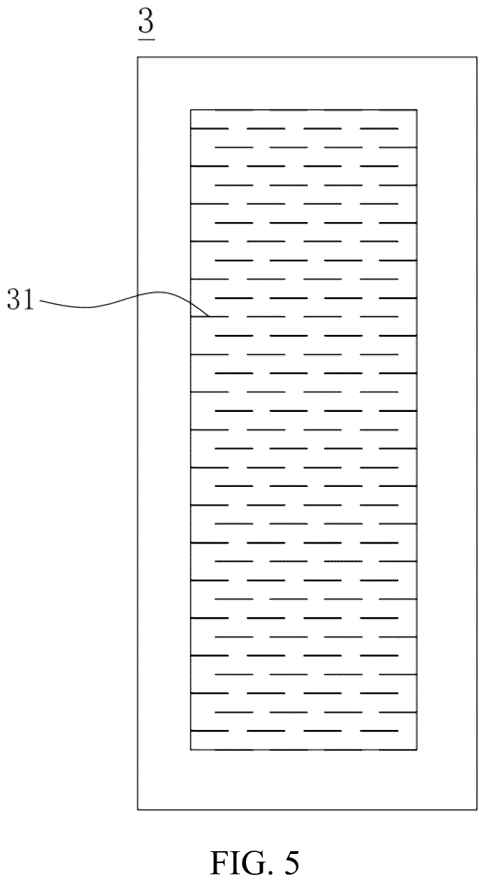

As shown in FIG. 5, the flow guide openings 31 can alternatively arranged horizontally in the flow guide plate 3 to increase sideway airflow for accelerating dissipation of heat inside the cabinet body 4.

Based on the same inventive idea, the present invention also provides a data cabinet heat-dissipating method. The data cabinet heat-dissipating method comprises the following step:
arranging a front-door cooling assembly, an air exhaust assembly 1, and a rear-door cooling assembly 1 sequence in a cabinet body 4, wherein heat inside the cabinet body 4 passes through the front-door cooling assembly and a water-cooling radiator 2 of the front-door cooling assembly brings away the heat inside the cabinet body 4, and a water-cooling radiator 2 of the rear-door cooling assembly also brings away heat, so that the front-door cooling assembly and the rear-door cooling assembly forms circulating cooling to hot air inside the cabinet body 4 to lower down a temperature inside the cabinet body 4, and also, the air exhaust assembly 1 drains the hot air inside the cabinet body 4 to outside of the cabinet body 4 for heat exchange to lower down the temperature inside the cabinet body 4. The front-door cooling assembly and the rear-door cooling assembly form circulating cooling for hot air inside the cabinet body 4 to lower down a temperature inside the cabinet body 4, and cold water at a relatively low temperature flows through an inlet into the water-cooling radiator 2 to have the hot air of the server and the water-cooling radiator 2 exchange heat to achieve efficient heat exchange with the water-cooling radiator 2 and fulfill heat exchange between the hot air of the cabinet body 4 and the water-cooling radiator 2 to convey heat to the outside for cooling, and also, the hot air of the cabinet body 4 is drained out of the cabinet body 4 by means of the air exhaust assembly 1 to lower down the temperature inside the cabinet body 4.

### Embodiment 2

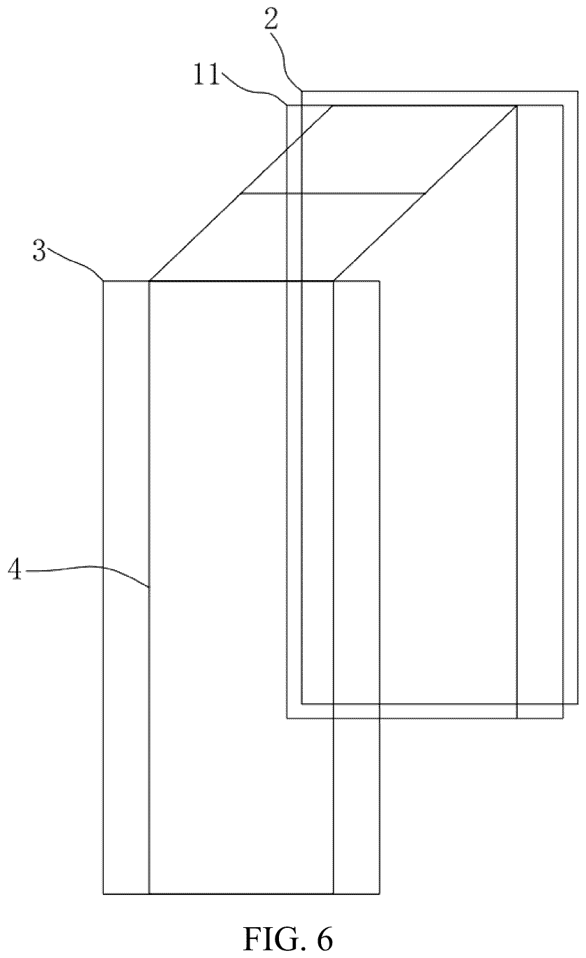

As shown in FIG. 6, in another embodiment of the present invention, the front-door cooling assembly of the data cabinet heat-dissipating system comprises a flow guide plate 3 and hinges. The flow guide plate 3 is fixedly connected to the hinges, and the hinges are fixedly connected to the cabinet body 4. The flow guide plate 3 is rotatably connected, by means of hinges, to the cabinet body 4. The flow guide plate 3 is formed with flow guide openings 31, and the flow guide openings 31 are arranged as plural ones and are uniformly arranged on the flow guide plate 3. The flow guide openings 31 are extremely small, and when air passes through the flow guide openings 31, external air is accelerated to move into the cabinet to lower down the temperature inside the cabinet. Further, two flow guide plates 3 are provided, and each of the flow guide plates 3 is provided with two corresponding hinges, and is fixedly connected to the hinges.

In the data cabinet body heat-dissipating system and method provided in the present invention, heat inside the cabinet body 4 passes through the flow guide plate 3 of the front-door cooling assembly, and the flow guide openings 31 of the flow guide plate 3 accelerates entry of external air into the cabinet body 4. When a server inside the cabinet body 4 generates heat, air flowing through the flow guide plate 3 as minute airflows makes the air penetrating to push hot air in the cabinet body 4 toward the water-cooling radiator 2, and the water-cooling radiator 2 of the front-door cooling assembly brings away the heat in the cabinet body 4, and also, heat is brought away by the water-cooling radiator 2 of the rear-door cooling assembly. The front-door cooling assembly and the rear-door cooling assembly form circulating cooling for the hot air inside the cabinet body 4 to lower down the temperature inside the cabinet body 4, and cold water at a relatively low temperature flows through an inlet into the water-cooling radiator 2 to have the hot air of the server and the water-cooling radiator 2 exchange heat to achieve efficient heat exchange with the water-cooling radiator 2 and fulfill heat exchange between the hot air of the cabinet body 4 and the water-cooling radiator 2 to convey heat to the outside for cooling, and also, the hot air of the cabinet body 4 is drained out of the cabinet body 4 by means of the air exhaust assembly 1 to lower down the temperature inside the cabinet body 4.

I claim:

1. A data cabinet heat-dissipating system, comprising a cabinet body, a front-door cooling assembly, an air exhaust assembly, and a rear-door cooling assembly, wherein the front-door cooling assembly, the air exhaust assembly, and the rear-door cooling assembly are arranged, in sequence, on the cabinet body, the front-door cooling assembly being arranged at a front end of the cabinet body and located at one side of the air exhaust assembly, the front-door cooling assembly transferring heat inside the cabinet body to outside, the air exhaust assembly being arranged between the front-door cooling assembly and the rear-door cooling assembly and arranged on the cabinet body, the air exhaust assembly transferring heat inside the cabinet body to outside, the rear-door cooling assembly being arranged at a rear end of the cabinet body and located at one side of the air exhaust assembly, the rear-door cooling assembly transferring heat inside the cabinet body to outside.

2. The data cabinet heat-dissipating system according to claim 1, wherein the front-door cooling assembly comprises a flow guide plate and a hinge, the flow guide plate being fixedly connected to the hinge, the hinge being fixedly connected to the cabinet body, the flow guide plate being rotatably connected by the hinge to the cabinet body, the flow guide plate being formed with flow guide openings, the flow guide openings being arranged as plural ones that are uniformly arranged on the flow guide plate.

3. The data cabinet heat-dissipating system according to claim 2, wherein the flow guide plate is arranged as two such flow guide plates, each of the flow guide plates being correspondingly formed with two such hinges and fixedly connected to the hinges.

4. The data cabinet heat-dissipating system according to claim 1, wherein the front-door cooling assembly comprises a flow guide plate, a water-cooling radiator, and a protective screen, the flow guide plate, the water-cooling radiator, and the protective screen being fixedly connected to the cabinet body in sequence from inside to outside, the flow guide plate being formed with a plurality of flow guide openings, the flow guide openings transferring heat inside the cabinet body to outside.

5. The data cabinet heat-dissipating system according to claim 3, wherein the rear-door cooling assembly comprises an airflow guide plate and a water-cooling radiator, the airflow guide plate and the water-cooling radiator being fixedly connected to the cabinet body in sequence from inside to outside, the airflow guide plate being formed with airflow guide openings, the airflow guide openings transferring heat of the cabinet body to outside.

6. The data cabinet heat-dissipating system according to claim 4, wherein the rear-door cooling assembly comprises an airflow guide plate and a water-cooling radiator, the airflow guide plate and the water-cooling radiator being fixedly connected to the cabinet body in sequence from inside to outside, the airflow guide plate being formed with airflow guide openings, the airflow guide openings transferring heat of the cabinet body to outside.

7. The data cabinet heat-dissipating system according to claim 5, wherein the water-cooling radiator comprises a water cooling plate, heat conducting plates, and water cooling pipes, the water cooling plate being fixedly connected to the cabinet body, the heat conducting plates and the water cooling pipes being both fixedly connected to the water cooling plate, the heat conducting plates and the water cooling pipes being both arranged as plural ones, the heat conducting plates and the water cooling pipe being sequentially arranged and connected, the water cooling pipe being arranged, in a penetrating form, in the heat conducting plate, the water cooling pipes being of an S-shape.

8. The data cabinet heat-dissipating system according to claim 6, wherein the water-cooling radiator comprises a water cooling plate, heat conducting plates, and water cooling pipes, the water cooling plate being fixedly connected to the cabinet body, the heat conducting plates and the water cooling pipes being both fixedly connected to the water cooling plate, the heat conducting plates and the water cooling pipes being both arranged as plural ones, the heat conducting plates and the water cooling pipe being sequentially arranged and connected, the water cooling pipe being arranged, in a penetrating form, in the heat conducting plate, the water cooling pipes being of an S-shape.

9. The data cabinet heat-dissipating system according to claim 1, wherein the air exhaust assembly comprises ventilation plates and heat dissipation fans, the ventilation plates being arranged at a top side of the cabinet body, the ventilation plates being as four such ventilation plates, which are respectively located at four corners of the cabinet body, the ventilation plate being formed with a plurality of airflow passage openings, the heat dissipation fan being fixedly connected to one side of the ventilation plate, the heat dissipation fan discharging heat inside the cabinet body through the airflow passage openings to outside.

10. A data cabinet heat-dissipating method, wherein the data cabinet heat-dissipating method comprises the following step:
arranging a front-door cooling assembly, an air exhaust assembly, and a rear-door cooling assembly in sequence in a cabinet body, wherein heat inside the cabinet body passes through the front-door cooling assembly and a water-cooling radiator of the front-door cooling assembly brings away the heat inside the cabinet body, and a water-cooling radiator of the rear-door cooling assembly also brings away heat, so that the front-door cooling assembly and the rear-door cooling assembly forms circulating cooling to hot air inside the cabinet body to lower down a temperature inside the cabinet body, and also, the air exhaust assembly drains the hot air inside the cabinet body to outside of the cabinet body for heat exchange to lower down a temperature inside the cabinet body.

11. The data cabinet heat-dissipating method according to claim 10, wherein the front-door cooling assembly comprises a flow guide plate and a hinge, the flow guide plate being fixedly connected to the hinge, the hinge being fixedly connected to the cabinet body, the flow guide plate being rotatably connected by the hinge to the cabinet body, the flow guide plate being formed with flow guide openings, the flow guide openings being arranged as plural ones that are uniformly arranged on the flow guide plate.

12. The data cabinet heat-dissipating method according to claim 11, wherein the flow guide plate is arranged as two such flow guide plates, each of the flow guide plates being correspondingly formed with two such hinges and fixedly connected to the hinges.

13. The data cabinet heat-dissipating method according to claim 10, wherein the front-door cooling assembly comprises a flow guide plate, a water-cooling radiator, and a protective screen, the flow guide plate, the water-cooling radiator, and the protective screen being fixedly connected to the cabinet body in sequence from inside to outside, the flow guide plate being formed with a plurality of flow guide openings, the flow guide openings transferring heat inside the cabinet body to outside.

14. The data cabinet heat-dissipating method according to claim 12, wherein the rear-door cooling assembly comprises an airflow guide plate and a water-cooling radiator, the airflow guide plate and the water-cooling radiator being fixedly connected to the cabinet body in sequence from inside to outside, the airflow guide plate being formed with airflow guide openings, the airflow guide openings transferring heat of the cabinet body to outside.

15. The data cabinet heat-dissipating method according to claim 13, wherein the rear-door cooling assembly comprises an airflow guide plate and a water-cooling radiator, the airflow guide plate and the water-cooling radiator being fixedly connected to the cabinet body in sequence from inside to outside, the airflow guide plate being formed with airflow guide openings, the airflow guide openings transferring heat of the cabinet body to outside.

16. The data cabinet heat-dissipating method according to claim 14, wherein the water-cooling radiator comprises a water cooling plate, heat conducting plates, and water cooling pipes, the water cooling plate being fixedly connected to the cabinet body, the heat conducting plates and the water cooling pipes being both fixedly connected to the water cooling plate, the heat conducting plates and the water cooling pipes being both arranged as plural ones, the heat conducting plates and the water cooling pipe being sequentially arranged and connected, the water cooling pipe being arranged, in a penetrating form, in the heat conducting plate, the water cooling pipes being of an S-shape.

17. The data cabinet heat-dissipating method according to claim 15, wherein the water-cooling radiator comprises a water cooling plate, heat conducting plates, and water cooling pipes, the water cooling plate being fixedly connected to the cabinet body, the heat conducting plates and the water cooling pipes being both fixedly connected to the water cooling plate, the heat conducting plates and the water cooling pipes being both arranged as plural ones, the heat conducting plates and the water cooling pipe being sequentially arranged and connected, the water cooling pipe being arranged, in a penetrating form, in the heat conducting plate, the water cooling pipes being of an S-shape.

18. The data cabinet heat-dissipating method according to claim 10, wherein the air exhaust assembly comprises ventilation plates and heat dissipation fans, the ventilation plates being arranged at a top side of the cabinet body, the ventilation plates being as four such ventilation plates, which are respectively located at four corners of the cabinet body, the ventilation plate being formed with a plurality of airflow passage openings, the heat dissipation fan being fixedly connected to one side of the ventilation plate, the heat dissipation fan discharging heat inside the cabinet body through the airflow passage openings to outside.
